(19) United States
(12) Patent Application Publication
(10) Pub. No.: US 2012/0318318 A1
(43) Pub. Date: Dec. 20, 2012

(54) CIGS BASED THIN FILM SOLAR CELLS HAVING SHARED BYPASS DIODES

(75) Inventors: Burak Metin, San Jose, CA (US); Deepak Nayak, Fremont, CA (US); Mustafa Pinarbasi, Morgan Hill, CA (US)

(73) Assignee: SoloPower, Inc., San Jose, CA (US)

(21) Appl. No.: 13/163,485

(22) Filed: Jun. 17, 2011

(51) Int. Cl. H01L 31/05; H01L 31/18

(52) U.S. Cl. 136/244; 438/80; 257/E31.001

(57) ABSTRACT

A photovoltaic module comprises a first bypass diode and a first group of solar cells connected to the first bypass diode. The first group of solar cells comprises a first solar cell, a second solar cell connected in series to the first solar cell, and a third solar cell connected in parallel to the first solar cell.

### BACKGROUND

1. Field of the Inventions

Embodiments of the present invention generally relate to photovoltaic or solar module design and fabrication and, more particularly, to modules utilizing thin film solar cells.

2. Description of the Related Art

Solar cells are photovoltaic (PV) devices that convert sunlight directly into electrical energy. Solar cells can be based on crystalline silicon or thin films of various semiconductor materials, that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost advantages by employing deposition techniques widely used in the thin film industry. Group IBIIIAVIA compound photovoltaic cells including copper indium gallium diselenide (CIGS) based solar cells have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂, is formed on the conductive Mo film. The substrate 11 and the contact layer 12 form a base layer 13. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or the contact layer formed on the substrate as an absorber precursor, and are then reacted with S and/or Se in a high temperature annealing process.

After the absorber film 14 is formed, a transparent layer 15, for example, a CdS film, a ZnO film or a CdS/ZnO film-stack, is formed on the absorber film 14. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

There are two different approaches for manufacturing PV modules. In one approach that is applicable to thin film CdTe, amorphous Si and CIGS technologies, the solar cells are deposited or formed on an insulating substrate such as glass that also serves as a back protective sheet or a front protective sheet, depending upon whether the device is “substrate-type” or “superstrate-type”, respectively. In this case the solar cells are electrically interconnected as they are deposited on the substrate. In other words, the solar cells are monolithically integrated on the single-piece substrate as they are formed. These modules are monolithically integrated structures. For CdTe thin film technology, the superstrate is glass which also is the front protective sheet for the monolithically integrated module. In CIGS technology, the substrate is glass or polyimide and serves as the back protective sheet for the monolithically integrated module. In monolithically integrated module structures, after the formation of solar cells which are already integrated and electrically interconnected in series on the substrate or superstrate, an encapsulant is placed over the integrated module structure and a protective sheet is attached to the encapsulant. An edge seal may also be formed along the edge of the module to prevent water vapor or liquid transmission through the edge into the monolithically integrated module structure.

In standard CIGS as well as Si and amorphous Si module technologies, the solar cells can be manufactured on flexible conductive substrates such as aluminum or stainless steel foils. Due to its flexibility, a stainless steel substrate allows low cost roll-to-roll solar cell manufacturing techniques. For such cells that are fabricated on conductive substrates, the solar cells are not formed on the protective sheet, and the transparent layer and the conductive substrate form the opposite poles of the solar cells. Multiple solar cells can be electrically interconnected by stringing or shingling methods that establish electrical connection between the opposite poles of the solar cells. Such interconnected solar cells are then packaged in protective packages to form solar modules or panels. Many modules can also be combined to form large solar panels. The solar modules are constructed using various packaging materials to mechanically support and protect the solar cells contained in the packaging against mechanical damage. Each module typically includes multiple solar cells which are electrically connected to one another using the above mentioned stringing or shingling interconnection methods.

In the stringing or shingling process, the (+) terminal of one cell is typically electrically connected to the (−) terminal of the adjacent solar cell. For the Group IBIIIAVIA compound solar cell shown in FIG. 1, if the substrate 11 is a conductive material such as a metallic foil, the substrate, which forms the bottom contact of the cell, becomes the (+) terminal of the solar cell. The metallic grid (not shown) deposited on the transparent layer 15 is the top contact of the device and becomes the (−) terminal of the cell. When interconnected by a shingling process, individual solar cells are placed in a staggered manner so that a bottom surface of one cell, i.e. the (+) terminal, makes direct physical and electrical contact to a top surface, i.e. the (−) terminal, of an adjacent cell. Therefore, there is no gap between two shingled cells. Stringing is typically done by placing the cells side by side with a small gap between them and using conductive wires or ribbons that connect the (+) terminal of one cell to the (−) terminal of an adjacent cell. Solar cell strings obtained by stringing or shingling individual solar cells are interconnected to form circuits. Circuits may then be packaged in protective packages to form modules. Each module typically includes a plurality of strings of solar cells which are electrically connected to one another.

As shown in FIG. 2B in a cross-sectional view, the PV module 50 such as shown in FIG. 2A is constructed using various packaging materials to mechanically support and protect the solar cells in it against mechanical and moisture damage. The most common packaging technology involves lamination of circuits in transparent encapsulants. In a lamination process, in general, the electrically interconnected solar cells 52 are covered with a transparent and flexible encapsulant layer 58 which fills any hollow space among the cells and tightly seals them into a module structure, preferably covering both of their surfaces. A variety of materials are used as encapsulants, for packaging solar cell modules, such as ethylene vinyl acetate copolymer (EVA), thermoplastic polyurethanes (TPU), and silicones. However, in general, such encapsulant materials are moisture permeable; therefore, they must be further sealed from the environment by a protective shell, which forms resistance to moisture transmission into the module package. The nature of the protective shell 56 determines the amount of water vapor that can enter the module 50. The protective shell 56 typically includes a front protective sheet 60A and a back protective sheet 60B and optionally an edge sealant 60C that is at the periphery of the module structure. The top protective sheet 60A is typically glass which is water impermeable. The back protective sheet 60B may be a sheet of glass or a polymeric sheet. The back protective sheet 60B may not have a moisture barrier layer in its structure such as a metallic film like an aluminum film. Light enters the module through the front protective sheet 60A. The edge sealant 60C is a moisture barrier material that may be in the form of a viscous fluid which may be dispensed from a nozzle to the peripheral edge of the module structure or it may be in the form of a tape which may be applied to the peripheral edge of the module structure. The edge sealant in Si-based modules is not between the top and bottom protective sheets but rather in a frame 65 which is attached to the edge of the module.

Flexible module structures may be constructed using flexible CIGS or amorphous Si solar cells. Flexible modules are light weight, and unlike the standard glass based Si solar modules, are unbreakable. Therefore, packaging and transportation costs for the manufactured flexible modules are much lower than for solar cell or module structures formed on glass that are not flexible and are easily damaged by mishandling. However, manufacture of flexible module structures is challenging in respects that are different from solar cell and module structures formed on glass that are not flexible. Further, while glass handling equipment used in glass based PV module manufacturing is fully developed by many equipment suppliers, handling of flexible sheets cannot be carried out using such standard equipment, and different equipment is required. Further, requirements are different for the flexible sheets that constitute the various layers in the flexible module structure. Various layers in flexible module structures may be cut into sizes that are close to the desired area of the module and encapsulation procedures may be carried out by handling and moving these pieces around.

As shown in FIGS. 2A-2B, solar cells 52 are typically interconnected in series to form circuits, which are then encapsulated to form the PV module 50. One important point relating to series connection of solar cells relates to shading of individual cells. If any one of the cells 52 in a cell string within a module is shadowed for a period, the shadowed cell may become reverse-biased due to the shadowing, in contrast to the other cells that receive light and are operational. Such reverse biasing of individual cells may cause breakdown of that cell and its overheating, and degradation of the overall module output. To avoid such problems it is customary to use bypass diodes which are placed into a junction box 62 attached to the back protective sheet 60B of the PV module 50.

FIG. 3 illustrates a common electrical interconnection configuration for groups of solar cells 52 connected to bypass diodes. Although FIG. 3 represents a shingled configuration, such that a substrate portion of the second solar cell overlaps with a surface portion of the first solar cell, the same interconnections shown can be made for a stringing configuration. As shown, a bypass diode 72 is used for every group of 3 solar cells 52. For standard Si technology, the reverse breakdown voltage of the Si solar cells is large enough that a bypass diode may be used for every string containing 18-24 solar cells. Therefore, in Si solar modules 1, 2 or 3 bypass diodes are typically placed into junction boxes, which are attached onto the back surface of the modules, and these diodes are connected to the appropriate points on the cell strings within the module package. The reverse breakdown voltages of thin film solar cells such as amorphous Si or CIGS devices fabricated on flexible metallic substrates are much lower than those of Si solar cells. CIGS devices, for example, may display a reverse breakdown voltage in the range of 1-6V, compared to Si solar cells which typically have breakdown voltages more than 10V. This means that, high power thin film solar modules such as over 100 W CIGS modules may need more than 10 bypass diodes to properly protect the cells and assure that modules perform safely without hot spots. However, bypass diodes are expensive, and it is not practical to place so many bypass diodes in a junction box outside the module package. Therefore, there is a need for a way to make solar cells with bypass diode protection in a less expensive manner.

### SUMMARY

The aforementioned needs are satisfied by embodiments of the present invention which, in a photovoltaic module comprises a first bypass diode and a first group of solar cells connected to the first bypass diode. The first group of solar cells comprises a first solar cell, a second solar cell connected in series to the first solar cell, and a third solar cell connected in parallel to the first solar cell.

The photovoltaic module may also comprise a second bypass diode, and a second group of solar cells connected to the second bypass diode, wherein the second group of solar cells is connected in series to the first group of solar cells. The second group of solar cells may also comprise a first solar cell, a second solar cell connected in series to the first solar cell, and a third solar cell connected in parallel to the first solar cell.

In one implementation, the first group of solar cells may further comprise a fourth solar cell connected in series to the third solar cell, wherein the first and second solar cells are connected in parallel to the third and fourth solar cells. The second group of solar cells may further comprise a fourth solar cell connected to the third solar cell in series, wherein the first and second solar cells are connected in parallel to the third and fourth solar cells.

In another implementation, the first group of solar cells further comprises a fourth solar cell connected in series to the second solar cell. In this implementation, the first, second and fourth solar cells of the first group are arranged in a shingled relationship such that a surface of the fourth solar cell comprising a terminal of a first polarity rests on a surface of the second solar cell comprising a terminal of a second polarity opposite the first, and a surface of the second solar cell comprising a terminal of the first polarity rests on a surface of the first solar cell comprising a terminal of the second polarity. The first group of solar cells may further comprise a fifth solar cell connected in series to the third solar cell, and a sixth solar cell connected in series to the fifth solar cell. In this implementation, the third, fifth and sixth solar cells of the first group are arranged in a shingled relationship such that a surface of the sixth solar cell comprising a terminal of a first polarity rests on a surface of the fifth solar cell comprising a terminal of a second polarity opposite the first, and a surface of the fifth solar cell comprising a terminal of the first polarity rests on a surface of the third solar cell comprising a terminal of the second polarity.

### BRIEF DESCRIPTION OF THE DRAWINGS

FIG. 1 is a schematic view of a thin film solar cell;

FIG. 2A is a schematic top view of a prior art photovoltaic module;

FIG. 2B is a schematic cross sectional view of the module of FIG. 2A;

FIG. 3 is a schematic view of a prior art photovoltaic module including bypass diodes;

FIG. 4 is a schematic view of a photovoltaic module according to an embodiment of the invention including bypass diodes; and

FIG. 5 is a schematic view of a photovoltaic module according to another embodiment of the invention including bypass diodes.

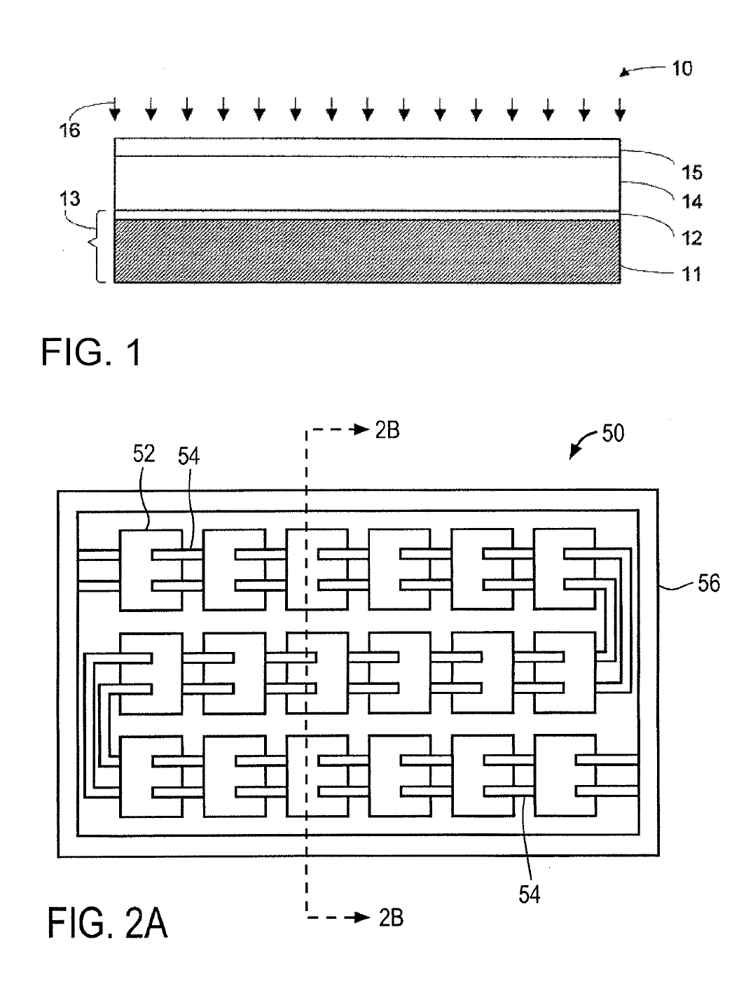

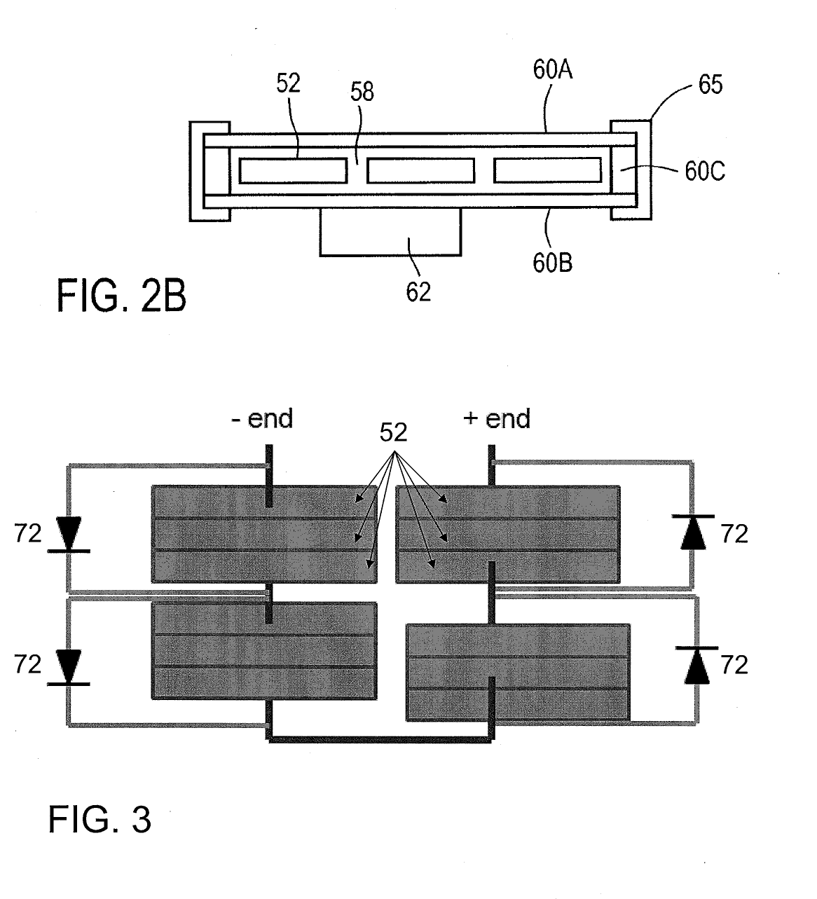

### DETAILED DESCRIPTION OF THE PREFERRED EMBODIMENTS

The embodiments described herein provide methods of interconnecting solar cells or photovoltaic (PV) cells. Embodiments will be described with reference to specific interconnected solar cell configurations or arrays. However, it will be appreciated that embodiments of the present invention may be practiced with other configurations without departing from the scope of the present invention.

Embodiments described herein provide module structures and methods of manufacturing rigid or flexible PV modules employing thin film solar cells fabricated on flexible substrates, preferably on flexible metallic foil substrates. The solar cells may be Group IBIIIAVIA compound solar cells fabricated on thin stainless steel or aluminum alloy foils. The modules may each include a moisture resistant protective shell within which the interconnected solar cells or cell strings are packaged and protected. The protective shell may comprise a moisture barrier top protective sheet through which the light may enter the module, a moisture barrier bottom protective sheet, a support material or encapsulant covering at least one of a front side and a back side of each cell or cell string. The support material may be used to fully encapsulate each solar cell and each string, top and bottom. The protective shell may additionally comprise a moisture sealant that is placed between the top protective sheet and the bottom protective sheet along the circumference of the module and forms a barrier to moisture passage from outside into the protective shell from the edge area along the circumference of the module. At least one of the top protective sheet and the bottom protective sheet of the present module may be glass for rigid structures. For flexible modules, the top and bottom protective sheets may be flexible materials that have a moisture transmission rate of less than 10⁻³ gm/m²/day, preferably less than 5×10⁴ gm/m²/day.

In one embodiment, a solar cell string including two or more solar cells is formed by interconnecting the solar cells. At least one bypass diode may be connected in parallel but with opposite polarity to the solar cells, as further described below. The bypass diodes may be placed into a junction box that is attached to the exposed back protective sheet of the PV module, right below the interconnected solar cells, using moisture barrier adhesives. Terminals of the interconnected solar cells may be connected to the junction box through holes formed in the back protective sheet. In this way, the size of the module may be maintained as the frame holding the cells can be positioned very close to the solar cells. The holes in the back protective sheet must be very carefully sealed against moisture leakages using, for example, potting materials such as silicone, epoxy, butyl, and urethane containing materials. If the seal in the holes fails, such holes allow moisture to enter the module and can cause device failures. Alternatively, the bypass diode may be electrically connected to the conductive back surfaces of at least two solar cells, each solar cell having a back conductive surface and a front light receiving surface. The bypass diode and the solar cells may be further encapsulated with support material such that the bypass diode is placed between at least one solar cell and the bottom protective sheet.

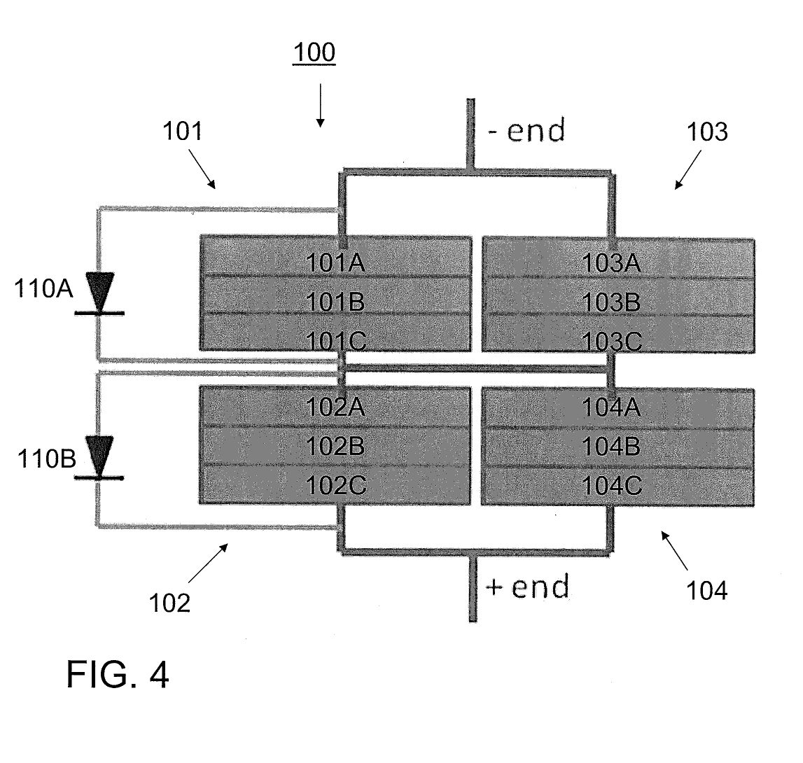

FIG. 4 shows a schematic view of a PV module 100, which includes cell group 101, including solar cells 101A, 101B and 101C, cell group 102, including solar cells 102A, 102B and 102C, cell group 103, including solar cells 103A, 103B and 103C, and cell group 104, including solar cells 104A, 104B and 104C. Although FIG. 4 represents a shingled solar cell configuration, such that a substrate portion of the second solar cell overlaps with a surface portion of the first solar cell, the same interconnections shown can be made for a stringing solar cell configuration.

Specifically, in cell group 101, the top surface of solar cell 101A is a (−) terminal, and the bottom surface of solar cell 101A is a (+) terminal, which connects in series to the top surface of solar cell 101B, which is a (−) terminal. The bottom surface of solar cell 101B is a (+) terminal, which connects in series to the top surface of solar cell 101C, which is a (−) terminal. The bottom surface of solar cell 101C is a (+) terminal, and connects to cell group 102, by connecting in series to the top surface of solar cell 102A, which is a (−) terminal.

Likewise, in cell group 103, the top surface of solar cell 103A is a (−) terminal, and the bottom surface of solar cell 103A is a (+) terminal, which connects in series to the top surface of solar cell 103B, which is a (−) terminal. The bottom surface of solar cell 103B is a (+) terminal, which connects in series to the top surface of solar cell 103C, which is a (−) terminal. The bottom surface of solar cell 103C is a (+) terminal, and connects to cell group 104, by connecting in series to the top surface of solar cell 104A, which is a (−) terminal.

In the illustrated embodiment, a bypass diode 110A is connected to the pair of cell groups 101/103, and a bypass diode 110B is connected to the pair cell groups 102/104. In contrast to the interconnection configuration in FIG. 3, in which each solar cell group is interconnected to adjacent solar cells in series, in the illustrated embodiment, the cell groups 101 and 103 are connected to each other in parallel, while cell groups 102 and 104 are also connected to each other in parallel. Moreover, in FIG. 3, a bypass diode is used for every 3 solar cells in each cell group. In contrast, in the embodiment of FIG. 4, a pair of parallel-connected cell groups 101/103 is connected in series to a pair of parallel-connected cell groups 102/104, and therefore one bypass diode is used for each pair of cell groups. Thus, the number of bypass diodes in the illustrated embodiment is reduced in half compared to the number of bypass diodes in the example of FIG. 3, for the same number of cells arranged on the same surface area of a PV module. Accordingly, embodiments of the invention can significantly reduce material costs, by at least a half compared to conventional devices, due to the reduced total number of bypass diodes used.

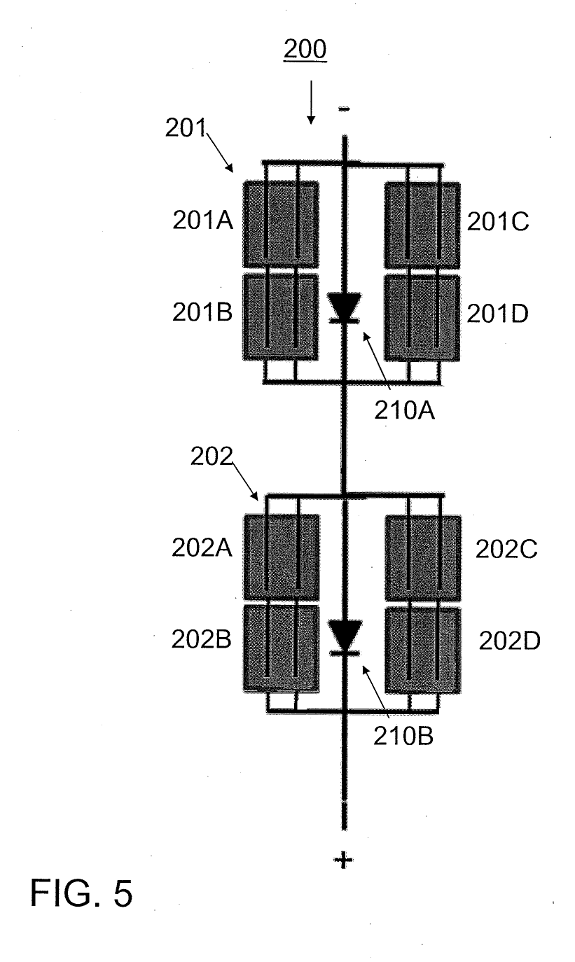

FIG. 5 shows a schematic view of a PV module 200, which includes cell group 201, including solar cells 201A, 201B, 201C and 201D, and cell group 202, including solar cells 202A, 202B, 202C and 202D. Specifically, for the cell group 201, the top surface of solar cell 201A is a (−) terminal, and the bottom surface of solar cell 201A is a (+) terminal, which connects in series to the top surface of solar cell 201B, which is a (−) terminal. Likewise, the top surface of solar cell 201C is a (−) terminal, and the bottom surface of solar cell 201C is a (+) terminal, which connects in series to the top surface of solar cell 201D, which is a (−) terminal. The pair of serial-connected solar cells 201A/201B is connected to the pair of serial-connected solar cells 201C/201D in parallel. A bypass diode 210A is connected to the cell group 201, including solar cells 201A, 201B, 201C and 201D.

Similarly, for the cell group 202, the top surface of solar cell 202A is a (−) terminal, and the bottom surface of solar cell 202A is a (+) terminal, which connects in series to the top surface of solar cell 202B, which is a (−) terminal. Likewise, the top surface of solar cell 202C is a (−) terminal, and the bottom surface of solar cell 202C is a (+) terminal, which connects in series to the top surface of solar cell 202D, which is a (−) terminal. The pair of serial-connected solar cells 202A/202B is connected to the pair of serial-connected solar cells 202C/202D in parallel. A bypass diode 210B is connected to the cell group 202, including solar cells 202A, 202B, 202C and 202D. The cell group 201 is thus connected to the cell group 202 in series, with a single bypass diode for each group of 4 interconnected solar cells.

Although FIG. 5 represents a stringing configuration, the same interconnections shown can be made for a shingled configuration. Moreover, the cells in each cell group that are connected in series, for example, solar cells 201A and 201B, or solar cells 201C and 201D, may also be in a shingled relationship such that one surface of a solar cell directly contacts and overlaps with another surface of an adjacent solar cell.

Thus, embodiments of the invention further reduce overall mismatch power losses by connecting groups of cells in parallel to each other. For example, for a solar cell configuration with an all-series interconnection scheme, current mismatches may affect the overall output of the module as the cell with the lowest current will control the overall module output. However, for interconnection schemes according to the embodiments shown for example in FIG. 4 and FIG. 5, the mismatches in both voltage and current may be accommodated because there is always a secondary path within the parallel paired cells 101/103 and 102/104 as shown in FIGS. 4, and 201A-B/201C-D and 202A-B/202C-D as shown in FIG. 5. Thus, embodiments of the invention can reduce problems of power losses due to current and voltage mismatches.

Although aspects and advantages of the present inventions are described herein with respect to certain preferred embodiments, modifications of the preferred embodiments will be apparent to those skilled in the art. Thus, the scope of the present invention should not be limited to the foregoing description, but should be defined by the appended claims.

What is claimed is:

1. A PV module, comprising:
a first bypass diode; and
a first group of solar cells connected to the first bypass diode,
wherein the first group of solar cells comprises a first solar cell, a second solar cell connected in series to the first solar cell, and a third solar cell connected in parallel to the first solar cell.

2. The PV module of claim 1, further comprising:
a second bypass diode; and
a second group of solar cells connected to the second bypass diode, wherein the second group of solar cells is connected in series to the first group of solar cells.

3. The PV module of claim 2, wherein the second group of solar cells comprises a first solar cell, a second solar cell connected in series to the first solar cell, and a third solar cell connected in parallel to the first solar cell.

4. The PV module of claim 3, wherein the first group of solar cells further comprises a fourth solar cell connected in series to the third solar cell, wherein the first and second solar cells are connected in parallel to the third and fourth solar cells.

5. The PV module of claim 4, wherein the second group of solar cells further comprises a fourth solar cell connected to the third solar cell in series, wherein the first and second solar cells are connected in parallel to the third and fourth solar cells.

6. The PV module of claim 3, wherein the first group of solar cells is arranged in a shingled relationship such that a surface of the second solar cell comprising a terminal of a first polarity contacts a surface of the first solar cell comprising a terminal of a second polarity opposite the first polarity.

7. The PV module of claim 3, wherein the first group of solar cells further comprises a fourth solar cell connected in series to the second solar cell.

8. The PV module of claim 7, wherein the first, second and fourth solar cells of the first group are arranged in a shingled relationship such that a surface of the fourth solar cell comprising a terminal of a first polarity contacts a surface of the second solar cell comprising a terminal of a second polarity opposite the first polarity, and a surface of the second solar cell comprising a terminal of the first polarity contacts a surface of the first solar cell comprising a terminal of the second polarity.

9. The PV module of claim 7, wherein the first group of solar cells further comprises a fifth solar cell connected in series to the third solar cell, and a sixth solar cell connected in series to the fifth solar cell.

10. The PV module of claim 9, wherein the third, fifth and sixth solar cells of the first group are arranged in a shingled relationship such that a surface of the sixth solar cell comprising a terminal of a first polarity contacts a surface of the fifth solar cell comprising a terminal of a second polarity opposite the first polarity, and a surface of the fifth solar cell comprising a terminal of the first polarity contacts a surface of the third solar cell comprising a terminal of the second polarity.

11. The PV module of claim 9, wherein the second group of solar cells is arranged in a shingled relationship such that a surface of the second solar cell comprising a terminal of a first polarity contacts a surface of the first solar cell comprising a terminal of a second polarity opposite the first polarity.

12. The PV module of claim 9, wherein the second group of solar cells further comprises a fourth solar cell connected in series to the second solar cell.

13. The PV module of claim 12, wherein the first, second and fourth solar cells in the second group are arranged in a shingled relationship such that a surface of the fourth solar cell comprising a terminal of a first polarity contacts a surface of the second solar cell comprising a terminal of a second polarity opposite the first polarity, and a surface of the second solar cell comprising a terminal of the first polarity contacts a surface of the first solar cell comprising a terminal of the second polarity.

14. The PV module of claim 12, wherein the second group of solar cells further comprises a fifth solar cell connected in series to the third solar cell, and a sixth solar cell connected in series to the fifth solar cell.

15. The PV module of claim 14, wherein the third, fifth and sixth solar cells of the second group are arranged in a shingled relationship such that a surface of the sixth solar cell comprising a terminal of a first polarity contacts a surface of the fifth solar cell comprising a terminal of a second polarity opposite the first polarity, and a surface of the fifth solar cell comprising a terminal of the first polarity contacts a surface of the third solar cell comprising a terminal of the second polarity.

16. A method of forming a PV module, comprising:
interconnecting a plurality of solar cells into a first group of solar cells, wherein the first group of solar cells comprises a first solar cell, a second solar cell connected in series to the first solar cell, and a third solar cell connected in parallel to the first solar cell; and
connecting a first bypass diode to the first group of solar cells.

17. The method of claim 16, further comprising:
interconnecting a plurality of solar cells into a second group of solar cells, wherein the second group of solar cells comprises a first solar cell, a second solar cell connected in series to the first solar cell, and a third solar cell connected in parallel to the first solar cell, and wherein the second group of solar cells is connected in series with the first group of solar cells; and
connecting a second bypass diode to the second group of solar cells.

18. The method of claim 17, wherein the first group of solar cells further comprises a fourth solar cell connected in series to the third solar cell, wherein the first and second solar cells are connected in parallel to the third and fourth solar cells, and wherein the second group of solar cells further comprises a fourth solar cell connected to the third solar cell in series, wherein the first and second solar cells are connected in parallel to the third and fourth solar cells.

19. The method of claim 17, wherein the first group of solar cells further comprises a fourth solar cell connected in series to the second solar cell, a fifth solar cell connected in series to the third solar cell, and a sixth solar cell connected in series to the fifth solar cell, and wherein the second group of solar cells further comprises a fourth solar cell connected in series to the second solar cell, a fifth solar cell connected in series to the third solar cell, and a sixth solar cell connected in series to the fifth solar cell.

20. A photovoltaic module comprising:
a first group of solar cells connected together so that each solar cell of the group increases the voltage output of the first group in response to receiving sunlight;
a second group of solar cells connected together so that each solar cell of the group increases the voltage output of the second group in response to receiving sunlight wherein the first and second groups are connected so that the voltage output of the module is the greater of the voltage output of the first or second group; and
a bypass diode that is connected to the first and second group of solar cells such that the bypass diode inhibits reverse bias of the first or second group of solar cells when one or more cells of the first or second groups of solar cells are reverse biased.

21. The module of claim 20, wherein the cells that comprise first and second groups of cells are connected in series and wherein the first and second group of cells are connected in parallel with each other and with the bypass diode.

22. The module of claim 20, wherein the cells of the first and second solar groups are connected via shingling.

23. The module of claim 20, wherein the cells of the first and second solar cell groups are connected via stringing.
